(19) United States
(12) Patent Application Publication
(10) Pub. No.: US 2020/0240010 A1
(43) Pub. Date: Jul. 30, 2020

(54) DEVICE FOR INTERNALLY COATING CONTAINERS

(71) Applicant: KHS CORPOPLAST GMBH, Hamburg (DE)

(72) Inventors: Sebastian KYTZIA, Todesfelde (DE); Bernd-Thomas KEMPA, Hamburg (DE); Philipp LANGHAMMER, Hamburg (DE); Andreas VOGELSANG, Hamburg (DE)

(21) Appl. No.: 16/607,628

(22) PCT Filed: Apr. 26, 2018
(86) PCT No.: PCT/EP2018/060648

§ 371 Date: Oct. 23, 2019

(30) Foreign Application Priority Data
Apr. 26, 2017 (DE) 10 2017 108 992.6

(51) Int. Cl. C23C 16/04; C23C 16/40; C23C 16/455; C23C 16/511; H01J 37/32

(52) U.S. Cl. CPC C23C 16/045; C23C 16/401; C23C 16/45578; H01J 37/3244; H01J 37/3222; H01J 37/32394; H01J 37/32403; C23C 16/511

(57) ABSTRACT

A device for coating containers, in particular bottles, including a vacuum chamber, a plasma generator, and a gas lance having an outlet opening protruding into the container for introducing a material to be deposited on an inner wall of the container. The inside diameter of the gas lance in a region of the outlet opening is enlarged relative to the inside diameter in a main section of the gas lance.

### FIELD OF INVENTION

The present invention relates to plasma treatment of containers, and more specifically, to a gas lance of a container coating device for introducing a coating material on an inner wall of the containers.

### BACKGROUND OF INVENTION

There is an increasing trend at the present time for containers, such as, for example, PET bottles, to be coated on the interior, for example with a thin SiOx layer. This internal coating is carried out in a coating device, which comprises a vacuum chamber to receive the container. The device further contains a plasma generator, such as a microwave generator, and a gas lance with an outlet opening protruding into the container for introducing a material to be deposited on the inner wall of the container. For example, a process gas, such as siloxane gas, is introduced into the container, which is deposited in the plasma formed by the plasma generator, then in the form of SiOx layers on the inner wall of the container. Such coating devices are known from DE 10 2010 023119 A1 or from EP 1 507 893 B1.

It is now to be taken into account that in the beverage industry sector such a coating device has a substantial throughput. For example, in one day tens of thousands of bottles can be coated and several thousand bottles per hour. One problem with such devices is that the outlet opening of the gas lance becomes clogged relatively quickly due to the coating. This requires frequent cleaning and more frequent replacement of the gas lance. The object of the invention is therefore to provide a coating device with which the expense and effort of maintenance and cleaning is reduced.

### SUMMARY OF THE INVENTION

This object is solved by a coating device in accordance with claim 1. Advantageous further embodiments of the invention are the object of the dependent claims. Advantageous embodiments of the invention are also presented in the description and the drawings.

According to the invention, the inside diameter of the gas lance in the region of the outlet opening is enlarged relative to the inside diameter of a main section of the gas lance. In this situation, the gas lance has a multiple function, in that it is by way of this gas lance that the introduction of the respective process gases for the coating takes place, and this gas lance further serves as an antenna for the electromagnetic field orientation in the vacuum chamber.

In an alternative embodiment, it is also possible, by means of the gas lance, for at least a part quantity of the gas to be suctioned out of the container and/or out of the vacuum chamber, as well as the relaxing gas, as a rule air, to be introduced. The main section forms the predominant part of the length of the gas lance, preferably more than 50%, and in particular more than 90%, of the length of the gas lance. In this main section, the inside diameter of the gas lance is preferably constant, i.e. a defined value.

According to the invention, the outlet opening is larger in relation to the conventional gas lance, in which up to now the outlet opening was defined solely by the inside diameter of the gas lance. Due to the enlarged outlet opening, the emerging process gas, such as, for example, siloxane, when emerging from the gas lance and entering into the plasma, is substantially less inclined to deposit SiOx layers on the end edge of the gas lance surrounding the outlet opening.

Since the gas lance is located in the spatial area of the coating process, it is subjected to the microwave field in the vacuum chamber. As a result, field elevations or field concentrations form on the outlet side, for example at the cylindrical tube end, which favours a preferred depositing of process products, such as SiOx, and therefore a growth of layers. This coating process leads, after a relatively short time, to a reduction of the outlet opening or of the outlet cross-section, such that the ideal flow relationships of the gas mixture are no longer provided, and the coating values are no longer attained.

The electromagnetic field orientation and field concentration in the widened opening is massively reduced. Added to this is the fact that the tendency of the process gas to form reduced vortices at the outer edge of the gas lance, which are very much fewer than with conventional cylindrical gas lances with constant inside diameters. Due to the fact that the outlet opening is widened, the inclination to the formation of deposits, as in the case of siloxane the formation of SiOx layers, at the end edge of the gas lance surrounding the outlet opening, is substantially less than with previous gas lances. Any deposits which do settle at the end edge, to a lesser degree than formerly, will therefore not lead so quickly to a reduction in the size of the outlet opening. The service interval times for the cleaning of the outlet opening or for replacing the gas lance can therefore be substantially lengthened.

In an advantageous further embodiment of the invention, the gas lance is widened in the shape of a trumpet in the region of the outlet opening. In this way, the inside diameter of the gas lance continually expands in the region of the outlet opening, such that no edge is formed at which vortices could occur. In addition to this, due to the widening of the outlet opening, the end edge is moved out of the direct jet range of the gas blown into the container by the gas lance. Accordingly, the tendency for the depositing of SiOx layers on the outer edge of the gas lance in the region of the outlet opening is very substantially reduced, which results in considerably longer service intervals for the cleaning of the gas lance. In this context, it is essentially not of consequence whether the widening of the inside diameter of the gas lance is also associated with an enlargement of its outer diameter. If this is the case, then the widening of the inside diameter can in any event be applied to an extent which goes beyond the wall thickness of the gas lance (this would be the restriction on the increase in the inside diameter, if the outer diameter of gas lance were to remain constant). The trumpet-shaped widening has the advantage that no edges are present on the inner surface of the gas lance, on which SiOx layers could be deposited.

In an alternative embodiment to this, the gas lance can also be widened in conical form in the region of the outlet opening. Such an embodiment is easier to manufacture, even if it not so favourable in terms of flow technology as a gas lance widened in the shape of a trumpet.

As an alternative or in addition, the inside diameter of the gas lance can be widened in the region of the outlet opening in relation to the inside diameter in a main section of the gas lance, i.e. for example as a widened cylindrical section. In this situation it is not absolutely necessary that the outer diameter of the gas lance be increased, but the larger inside diameter can be achieved, for example, by a reduction in the wall thickness of the gas lance. This can be produced very economically. This embodiment design can in principle also be combined with the trumpet-shaped or conical widening of the gas lance in the region of the outlet opening. In principle, simply a greater inside diameter of the gas lance in the region of the outlet opening in relation to the inside diameter in a main section of the gas lance is already sufficient to reduce the tendency to undesirable depositing at the outlet opening.

When reference is made here to the region of the outlet opening of the gas lance, this relates to the end section of the gas lance, for example the last 5 cm, in particular the last 3 cm, before the outlet opening.

Preferably, in the region of the outlet opening the gas lance consists of a different material than in a main section. In this way, for example, a material can be selected with which the tendency to the formation of deposits in the plasma process will be reduced. Such a material is, for example, a ceramic containing Al₂O₃.

Preferably, the gas lance consists at least in part of special steel, and/or at least in part of Al₂O₃. These two materials have proved their worth in the production of gas lances.

Advantageously, the gas lance is multi-part, with a main section, forming the larger axial length of the gas lance, and an axial shorter end section, in which the outlet opening is arranged. In this way, the end section of the gas lance can preferably be held to the main section of the gas lance in the region of the outlet opening in such a way that it can be replaced. In this way, the end section or the tip of the gas lance can be easily replaced when the cleaning of the end section comprising the outlet opening is no longer possible. Accordingly, it is not necessary for the entire gas lance to be replaced, which is economically advantageous. The connection between the main section and the end section is provided, for example, by means of friction or other inherently known detachable connection techniques (screw thread, bayonet fitting, etc.).

Preferably, the gas lance exhibits at the outlet opening an inside diameter which is at least twice as large, in particular three times as large, as the inside diameter in the main section of the gas lance. When reference is made in this Application to a main section of the gas lance, this relates to the axial large part of the gas lance, which preferably exhibits a constant inside diameter. This main section therefore forms the predominant part of the gas lance, which during the coating process intrudes in whole or in part into the bottle.

Preferably, the end section of the gas lance is arranged in a mounting part, which can be mounted onto the main section of the gas lance. In this way, not only is the tendency reduced for the SiOx layers to adhere to the gas lance in the region of the outlet opening, but, in the event of the outlet opening arranged in the mounting part becoming so heavily dirt contaminated that it can no longer be rendered clean, the mounting part with the outlet opening can be easily replaced. In this way, interruptions in the coating process can be reduced to a minimum in terms of time.

Preferably, the mounting part contains a sleeve, which engages around the main section of the gas lance and secures the mounting part on the main section. This securing arrangement can be formed by means of a friction grip, or also by a screw thread or bayonet closure, or other inherently known detachable connection techniques.

Preferably, the inside diameter of the mounting part corresponds, at its end facing towards the main section of the gas lance, to the inside diameter of the main section of the gas lance. In this way, no edge is formed at the connection between the main section and the mounting part of the gas lance which could incur vortices, and therefore lead to an increased depositing of the reaction products from the gas discharge, such as SiOx, on the inside wall or in the region of the outlet opening.

Preferably, the inside wall of the mounting part and the inside wall of the main section of the gas lance are flush with one another at their mutually facing ends. This not only leads to there being no step present at the connection point, but also that the inclination of the wall is even, whereby there is no crease present in the wall which in turn could lead to vortices in the gas being introduced. The inside diameter of the inside wall of the main section therefore merges smoothly into the inside wall of the mounting part, without any step, edge, or crease, the inside diameter of the mounting part being widened in the region of the outlet opening in relation to the inside diameter of the main section of the gas lance.

Preferably, the coating device is configured as a mass coating system with a coating capacity of at least 1,000 containers per hour, and in particular at least 10,000 containers per hour. The coating device contains not only the vacuum chamber, the receivers for the containers, in particular PET bottles, but also the entire movement mechanisms and robots, which arrange the bottles in the vacuum chamber above the gas lance. It is of course also possible in this arrangement for the gas lance to be moved axially into the container. The coating device is designed in particular for the SiOx coating of PET bottles, but can also be used for coating with other materials, for example for sterilising or hygiene treatment or fungicidal treatment, etc.

In an advantageous further embodiment of the invention, the end edge of the gas lance surrounding the outlet opening is rounded. This leads to a reduced inclination of the depositing of SiOx layers at this end edge, and therefore to a reduced inclination of the clogging of the outlet opening due to deposited SiOx layers. This in turn lengthens the service intervals, and therefore makes possible longer uninterrupted work cycles.

Preferably, the end edge of the gas lance surrounding the outlet opening is seamed outwards around the edges, which in turn reduces the tendency to the depositing of SiOx layers.

It is obvious to the person skilled in the art that the embodiment forms described heretofore can be combined with one another. In a mass coating device it is of course possible for a large number of vacuum chambers and a large number of gas lances to be arranged, in order, batch by batch or continuously, for a large number of containers, in particular PET bottles, to be coated simultaneously.

As a rule, in the coating device the gas lance is inserted from below, perpendicularly upwards into the container, in particular the PET bottle. Any other alignment of the gas lance in the vacuum chamber is, however, also possible. It is also possible for the gas lance to be held stationary during the coating process, or, during the coating process, to be moved into the container or out of the container.

Preferably, the inside diameter is constant in the main section of the gas lance.

### BRIEF DESCRIPTION OF THE DRAWINGS

The invention is described hereinafter by way of examples and on the basis of the schematic drawings in which:

FIG. 1a depicts a top plan view of a rotating coating device, in which the vacuum chambers can always accommodate and treat two containers,

FIG. 1b depicts a side section view through a vacuum chamber of a coating device and a gas lance and a microwave generator,

FIG. 2 depicts a detailed view of the upper end of the gas lance from FIG. 2 in a first embodiment,

FIG. 3 depicts a detailed view of the upper end of the gas lance from FIG. 1 in a second embodiment,

FIG. 4 depicts a sectional vertical cross-section view of a third embodiment of the upper end of the gas lance, with a mounting part, which comprises an outlet opening; and

FIG. 5 depicts a simple embodiment of a cylindrical gas lance with an enlarged inside diameter in the end section.

### DETAILED DESCRIPTION OF THE INVENTION

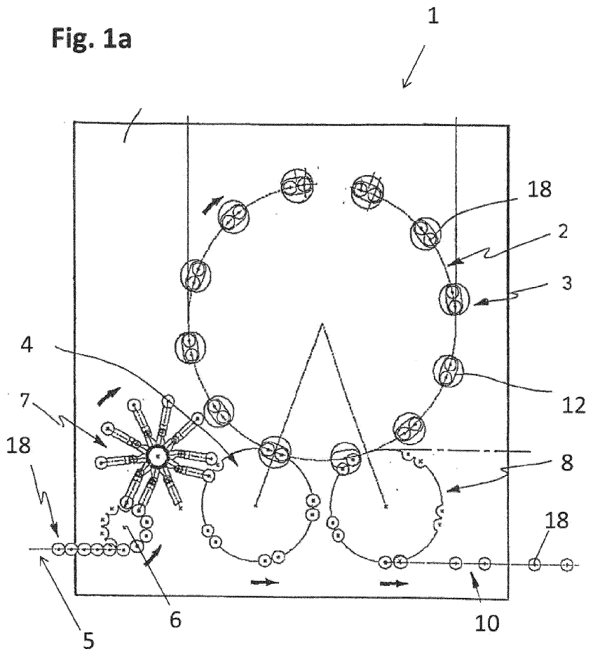

FIG. 1a shows a rotating coating device 1, on the transport wheel 2 of which are arranged the circulating coating stations 3, which in each case comprise a vacuum chamber 12, and wherein, in the example shown, two containers 18 can always be accommodated and treated. The delivery section 5 conveys the containers 18, transported standing upright, to a distributing star 6, by means of which the containers 18 are brought into the required uniform distance interval spacing. From there the containers 18 are taken over in pairs by a transfer star 7, comprising gripper elements, and transferred to a delivery wheel 4. From the delivery wheel 4, the containers 18 are then conveyed in pairs into the accommodation elements, not represented in greater detail, of the vacuum chambers 12, and are held there. In an analogous manner, treated containers 18 are released from the accommodation elements, and the containers 18 are conveyed by a discharge wheel 8 onto a discharge section 10.

Connected here, downstream, is usually a filling machine, not represented, or a device for decoration, such as a labelling machine or a printing machine.

FIG. 1b shows in a very schematic form a vacuum chamber 12 of the coating device 1, with a vacuum chamber 12, which is surrounded by a microwave generator 14. Held on a base plate 16 of the vacuum chamber 12, as a container, is a PET bottle 18, which is to be individually coated, in differentiation to the embodiment according to FIG. 1a. By means of the very schematically represented vacuum unit 9, the vacuum chamber 12 is brought to the required internal pressure. A gas lance 20 projects into the bottle 18. The gas lance 20 has a first main section 22, forming the longer axial part of the gas lance 20, and an end section 24, arranged in which is the outlet opening 26. This end section 24 of the gas lance 20, or its inside diameter, is widened in the region towards the outlet opening 26, as can be seen from the following detailed cross-section drawings 2 to 5, which show alternative embodiments of the gas lance 20 from FIG. 1.

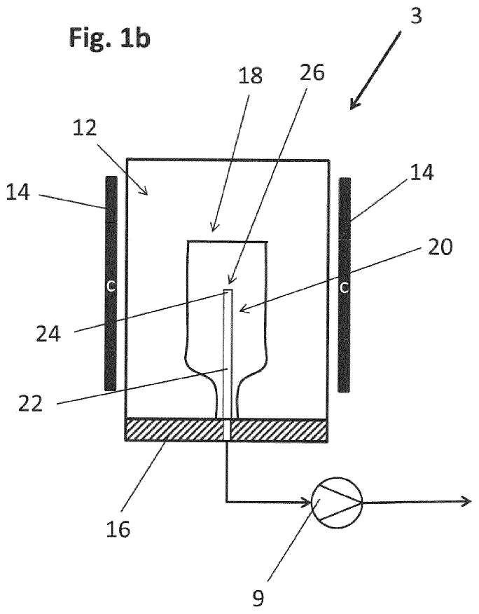

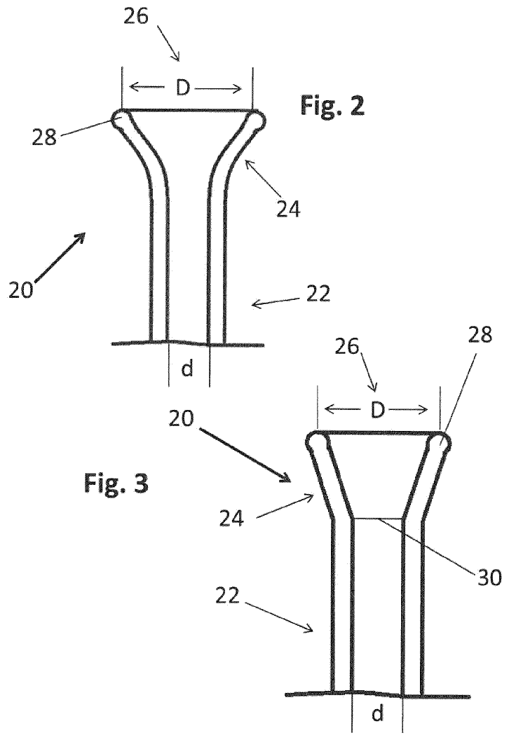

The end section 24 of the gas lance 20 in FIG. 2 is therefore widened in the shape of a trumpet, such that the diameter D of the outlet opening 26 is more than double the size of the inside diameter d of the gas lance 20 in the main section 22. Advantageous with this embodiment is the fact that the inner surface of the gas lance 20, between the main section 22 and the end section 24, is smooth and rounded, such that there is neither a step nor an edge present at that point at which vortices could occur. Preferably, therefore, the inner surface of the gas lance, between the main section 22 and the end section 24, is smooth and round, without any edges or corners. The end edge 28 of the end section 24 of the gas lance 20, which surrounds the outlet opening 26, is round, which in turn reduces the tendency to the depositing of SiOx layers at the end edge 28. FIG. 3 shows a largely identical embodiment to FIG. 2. Here, however, the end section 24 is not trumpet-shaped, but widened in conical form, which creates a small edge 30 between the main section and the end section 24 of the gas lance 20. Here too, the end edge 28 is rounded at the outlet opening 26, and even somewhat thickened in the form of a beading, which reduces the depositing of SiOx layers at this end edge 28. In terms of machining, this embodiment is easy and economical to produce.

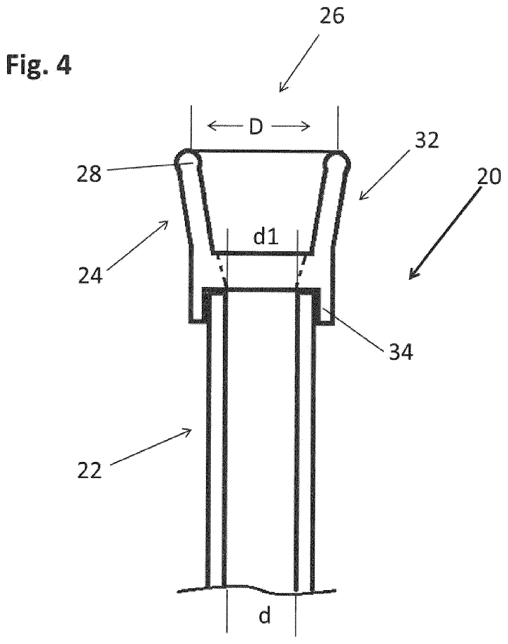

A further alternative embodiment of the gas lance 20 is represented in FIG. 4. Here, the main section 22 of the gas lance 20 is formed by a cylindrical tube with a defined inside diameter, mounted at the free upper end of which is a mounting part 32, which comprises a sleeve 34, which engages around the main section 22 of the gas lance 20 in order to secure the mounting part 32 on the main section 22. The mounting part 32 forms in this case, so to speak, the end section 24 of the gas lance 20. The mounting part 32 has at its end facing towards the main section 22 of the gas lance 20 an inside diameter dl, which corresponds to the inside diameter d of the main section 22 of the gas lance 20. In this way, in the inner region of the gas lance 20, there is no step between the main section 22 and the mounting part 32. The mounting part 32 is widened in conical fashion, in the same manner as the end section 24 of FIG. 3. Accordingly, the diameter D at the outlet opening 26 of the mounting part is about double the size of the inside diameter d of the main section of the gas lance 20. The mounting part 32 can be held by means of the sleeve 34, by friction grip or other connection means, such as screw thread or bayonet fitting, to the main section 22.

As an alternative or in addition, the sleeve 34 can also engage around the inner wall of the tubular main section 22. Here, it would then be possible for the wall thickness of the main section to be reduced on the inner side, such that, due to the rear engagement of the tube of the gas lance 20 by the sleeve 34, the inside diameter of the gas lance 20 is not reduced, and, additionally, no step is formed at which vortices could occur of the coating gas, in particular process gas, such as siloxane gas.

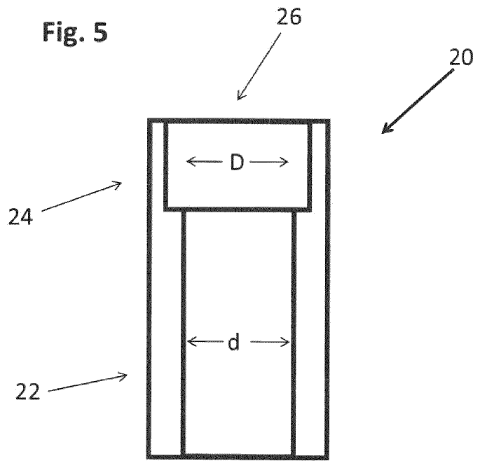

Finally, FIG. 5 shows a very simple embodiment of the invention, in which the end section 24 of the gas lance 20 exhibits in relation to the main section 22 simply an inside diameter D, which is greater than the inside diameter of the gas lance in the main section 22 of the gas lance 20. Although the technical flow properties are not so good as with the previous embodiments, this embodiment also leads to a reduced depositing of SiOx layers at the outlet opening.

It is obvious that the embodiments described heretofore do not restrict the basic principle of the invention. This can be varied within the framework of the following claims.

For example, the idea of the widened diameter of the end section 24 of the gas lance 20 in relation to the main section 22 (FIG. 5) can be combined with a following conical or trumpet-shaped widening of the end section 24, as is represented in FIGS. 2 and 3. Accordingly, the embodiments of FIGS. 5, 2 and 3 can be combined. It is also possible for only one region with enlarged diameter to be provided in the mounting part from FIG. 4, as is represented in FIG. 5. In particular, one of the foregoing embodiments can be put into application in coating stations on devices in accordance with DE 10 2010 023119 A1 or also EP 1 507 893 B1, or also in linear coating devices.

### REFERENCE NUMBER LIST

1 Coating device
2 Transport wheel
3 Coating station
4 Delivery wheel
5 Delivery section
6 Distributing star
7 Transfer star
8 Discharge wheel
9 Vacuum unit
10 Discharge section
12 Vacuum chamber
14 Microwave generator
6 Base plate
18 Container—PET bottle
20 Gas lance (e.g. for process gas delivery, such as siloxane)
22 Main section of the gas lance
24 End section of the gas lance
26 Outlet opening
28 End edge around the outlet opening
30 Edge between the main section and the end section
32 Mounting part
34 Sleeve

1. A device (1) for coating containers (18), comprising: a vacuum chamber (12), a plasma generator (14), and a gas lance with an outlet opening (26), which, when in operation in the intended manner, protrudes into the container (18) and serves to introduce a material which is to be deposited on the inner wall of the container (18), and serves as an antenna for the electromagnetic field orientation in the vacuum chamber, wherein the inside diameter (D) of the gas lance (20) in the region of the outlet opening (26) is enlarged relative to the inside diameter (d) in a main section (22) of the gas lance (20), wherein the gas lance (20) is widened in the region of the outlet opening (26) in a trumpet or conical shape.

2. The device (1) according to claim 1, wherein the inside diameter of the gas lance (20) in the region of the outlet opening (26) is greater than the inside diameter in a main section (22) of the gas lance (20).

3. The device (1) according to claim 1, wherein the gas lance (20) consists in the region of the outlet opening (26) of another material than in the main section (22).

4. The device (1) according to claim 1, wherein the gas lance (20) consists at least in part of special steel.

5. The device (1) according to claim 1, wherein the gas lance (20) consists at least in part of Al₂O₃.

6. The device (1) according to claim 1, wherein the gas lance (20) exhibits at the outlet opening (26) a diameter (D) which is at least two times larger than the inside diameter (d) of a main section (22) of the gas lance (20).

7. The device (1) according to claim 1, wherein the widened part of the gas lance (20) is arranged in a mounting part (32), which is held on the main section (22) of the gas lance (20) in a replaceable manner.

8. The device (1) according to claim 7, wherein the mounting part (32) comprises a sleeve (34), which engages around the main section (22) and secures the mounting part (32) on the main section (22).

9. The device (1) according to claim 7, wherein the inside diameter (dl) of the mounting part (32), at its end facing the main section (22) of the gas lance (20), corresponds to the inside diameter (d) of the main section (22) of the gas lance (20).

10. The device (1) according to claim 9, wherein the orientation of the inner wall of the mounting part (32) is flush with the inner wall of the main section (22) of the gas lance (20) at their mutually facing ends.

11. The device (1) according to claim 1, which is configured as a mass coating device with a coating capacity of at least 1,000 containers, and in particular at least 10,000 containers (18), per hour.

12. The device (1) according to a claim 1, wherein the plasma generator (14) is a microwave generator.

13. The device (1) according to claim 1, wherein an end edge (28) of the gas lance (20) is rounded at the outlet opening (26).

14. The device (1) according to claim 1, wherein an end edge (28) of the gas lance (20) is seamed outwards at the outlet opening (26).

15. The device (1) according to claim 1, wherein the gas lance (20) is configured as multi-part, wherein an end section (24) comprises the outlet opening (26) and a main section (22) forms the axially larger part of the gas lance (20), wherein the end section (24) is preferably held on the main section (22) in a replaceable manner.

16. The device according to claim 1 wherein the plastic containers are made from at least one of Polypropylene, Polyethylene, and Polyethylene terephthalate.
